(19) United States
(12) Patent Application Publication
(10) Pub. No.: US 2025/0096098 A1
(43) Pub. Date: Mar. 20, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: CHOONGBIN YIM, Suwon-si (KR)

(21) Appl. No.: 18/630,784

(22) Filed: Apr. 9, 2024

(30) Foreign Application Priority Data
Sep. 14, 2023 (KR) 10-2023-0122466

(51) Int. Cl. H01L 23/498; H01L 23/00; H01L 23/31; H01L 23/48; H01L 25/00; H01L 25/18

(52) U.S. Cl. CPC H01L 23/49838; H01L 23/3128; H01L 23/481; H01L 25/18; H01L 25/50; H01L 24/16; H01L 24/32; H01L 24/73; H01L 2224/16145; H01L 2224/32145; H01L 2224/73204; H01L 2924/1815

(57) ABSTRACT

A semiconductor package according to an embodiment includes a first semiconductor structure, including a first substrate, and a semiconductor stacking structure including a plurality of semiconductor dies on the first substrate and including a top surface, a second semiconductor structure on the first semiconductor structure, a second substrate, and a plurality of integrated circuit chips on the second substrate, a plurality of core balls between the first substrate and the second substrate and electrically connecting the first semiconductor structure and the second semiconductor structure, and a molding material for molding the semiconductor stacking structure and the plurality of core balls between the first substrate and the second substrate.

### CROSS-REFERENCE TO RELATED APPLICATION

This application claims priority to and the benefit of Korean Patent Application No. 10-2023-0122466 filed in the Korean Intellectual Property Office on Sep. 14, 2023, the entire contents of which are incorporated herein by reference.

### BACKGROUND OF THE INVENTION

### (a) Field of the Invention

The present disclosure relates to a semiconductor package and a method for manufacturing the same.

### (b) Description of the Related Art

The semiconductor industry is seeking to improve integration density so that more passive or active devices can be integrated within a given region. Among them, the development of technology to miniaturize the circuit line width of the semiconductor front-end process has gradually faced limitations. Accordingly, the semiconductor industry is in a trend of developing semiconductor packaging technology that can have a high integration density to compensate for the limitations of the semiconductor front-end process. This trend has led to the development of System in Package (SiP) technology, where active and passive devices are manufactured by placing them on a single substrate that serves as the main board.

In conventional SiP technology, devices such as processor chips, DRAM chips, display driver IC (DDI) chips, and sensor chips are mounted on the upper surface of the substrate using surface mount technology (SMT), and devices such as radio frequency IC (RFIC) chips and power management IC (PMIC) chips are mounted on the lower surface of the substrate using the SMT.

As such, the conventional SiP has a structure in which several devices are disposed on the upper and lower surfaces of the substrate. However, when multiple devices are disposed on the upper and lower surfaces of the substrate, it becomes difficult to reduce the thickness and area of the SiP.

Additionally, the SMT must be performed several times to dispose multiple devices on the top and lower surfaces of the substrate, respectively. Further, in order to increase board level reliability (BLR), an additional process such as underfill must be performed on each device. Therefore, the time and cost required to perform the process increase.

In addition, the conventional SiP used DRAM and AP, but recently, high-bandwidth memory (HBM) and chiplets are required to implement high-performance. In order to apply the HBM and chiplets to the SiP, the I/O with the fine interval of the HBM and the I/O with the fine interval of the chiplet must be connected to the substrate. However, in the conventional SiP structure, it is difficult to connect the I/O with the fine interval of the HBM and the I/O with the fine interval of the chiplet to the substrate.

Therefore, it is desirable to develop a new semiconductor package technology capable of addressing these issues of the conventional SiP.

### SUMMARY OF THE INVENTION

In some embodiments, as a bottom semiconductor structure, high-bandwidth memories (HBM) and a chiplet stacking structure may be disposed on a first substrate with bridge dies embedded therein, and the bridge dies may be used to electrically connect the I/O with fine intervals of the HBM and the I/O with fine intervals of the chiplet stacking structure.

According to some embodiments, as a top semiconductor structure, an RFIC chip, a sensor chip, a PMIC chip, and a DDI chip may be disposed on a second substrate within bridge dies embedded therein, and the bridge dies may be used to electrically connect I/O terminals with fine intervals of each of the RFIC chip, sensor chip, PMIC chip, and DDI chip to each other.

In some embodiments, by performing a single reflow process and a single underfill process, the RFIC chip, the sensor chip, the PMIC chip, and the DDI chip may be mounted on the second substrate.

In some embodiments, the bottom semiconductor structure and the upper semiconductor structure may be electrically connected using core balls, and the HBMs and the chiplet stacking structure may be disposed in a cavity by forming the cavity in the first substrate and the second substrate.

A semiconductor package according to an embodiment includes a first semiconductor structure, including: a first substrate; and a semiconductor stacking structure including a plurality of semiconductor dies on the first substrate and including a top surface; a second semiconductor structure on the first semiconductor structure, including: a second substrate; a plurality of integrated circuit chips on the second substrate; a plurality of core balls between the first substrate and the second substrate and electrically connecting the first semiconductor structure and the second semiconductor structure; and a molding material covering the semiconductor stacking structure and the plurality of core balls between the first substrate and the second substrate.

A semiconductor package according to an embodiment includes a first semiconductor structure, including: a first substrate; a first semiconductor stacking structure on the first substrate; a plurality of second semiconductor stacking structures on the first substrate and disposed on at least on two opposite sides of the first semiconductor stacking structure; a second semiconductor structure on the first semiconductor structure, including: a second substrate; and an RFIC chip, a DDI chip, a sensor chip, and a PMIC chip on the second substrate; a plurality of core balls between the first substrate and the second substrate and electrically connecting the first semiconductor structure and the second semiconductor structure; a first molding material covering the first semiconductor stacking structure, the plurality of second semiconductor stacking structures, and the plurality of core balls between the first substrate and the second substrate; and a second molding material covering the RFIC chip, the DDI chip, the sensor chip, and the PMIC chip on the second substrate.

A method for manufacturing a semiconductor package according to an embodiment includes: mounting a semiconductor stacking structure on a first substrate; bonding a plurality of core balls on the first substrate; bonding a second substrate on the plurality of core balls; molding the semiconductor stacking structure and the plurality of core balls with a molding material between the first substrate and the second substrate; and mounting an RFIC chip, a DDI chip, a sensor chip, and a PMIC chip on the second substrate.

As the bottom semiconductor structure, the HBMs and the chiplet stacking structure may be disposed on the first substrate with the bridge dies embedded therein, and the bridge dies may be used to electrically connect the I/O with fine interval of the HBM and the I/O with fine interval of the chiplet stacking structure. In addition, as the top semiconductor structure, the RFIC chip, sensor chip, PMIC chip, and DDI chip may be disposed on the second substrate within the bridge dies embedded therein, and the bridge dies may be used to electrically connect I/O terminals with fine intervals of each of the RFIC chip, sensor chip, PMIC chip, and DDI chip to each other. With this, high-performance HBMs, chiplet stacking structures, RFIC chips, sensor chips, PMIC chips, and DDI chips may be applied to the semiconductor package.

By performing a single reflow process and a single underfill process, the RFIC chip, the sensor chip, the PMIC chip, and the DDI chip may be mounted on the second substrate. Accordingly, the time and cost required to perform the process can be reduced.

The bottom semiconductor structure and the upper semiconductor structure may be electrically connected using core balls, and the HBMs and the chiplet stacking structure may be disposed in a cavity by forming the cavity in the first substrate and the second substrate. Accordingly, the thickness and area of the semiconductor package can be reduced.

### BRIEF DESCRIPTION OF THE DRAWINGS

FIG. 1 is a cross-sectional view illustrating a semiconductor package according to an embodiment.

FIG. 2 is a cross-sectional view illustrating a core ball according to an embodiment.

FIG. 3 is a cross-sectional view illustrating a core ball according to another embodiment.

FIG. 4 is a cross-sectional view illustrating a core ball according to another embodiment.

FIG. 5 is a cross-sectional view illustrating a semiconductor package according to another embodiment.

FIG. 6 is a cross-sectional view illustrating a semiconductor package according to another embodiment.

FIGS. 7 to 16 are cross-sectional views illustrating a method for manufacturing the semiconductor package according to the embodiment of FIG. 1.

### DETAILED DESCRIPTION OF THE EMBODIMENTS

Hereinafter, the present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Size and thickness of each constituent element in the drawings are arbitrarily illustrated for better understanding and ease of description, the following embodiments are not limited thereto.

Throughout the specification, when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between,” “adjacent” versus “directly adjacent,” etc.). In addition, unless explicitly described to the contrary, the word “comprise”, and variations such as “comprises” or “comprising”, will be understood to imply the inclusion of stated elements but not the exclusion of any other elements.

Further, when an element is referred to as being “on” or “above” a reference element, it can be positioned above or below the reference element, depending on the orientation, and it is not necessarily referred to as being positioned “on” or “above” in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Certain features are described herein in the singular, though they are provided in plural, as can be seen in the various figures or can be understood from the context in which they are described.

Hereinafter, a semiconductor package 100 and a method for manufacturing the semiconductor package 100 according to an embodiment will be described with reference to the drawings.

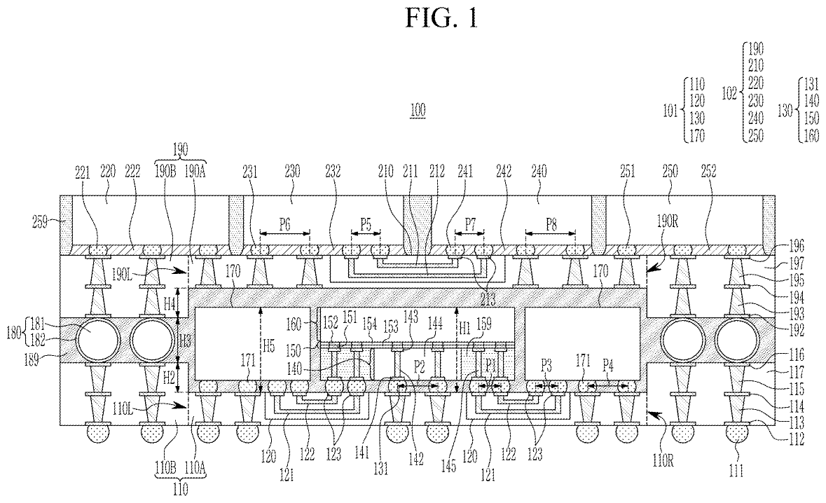

FIG. 1 is a cross-sectional view illustrating a semiconductor package 100 according to an embodiment.

Referring to FIG. 1, the semiconductor package 100 includes a lower semiconductor structure (first semiconductor structure; 101), core balls 180, a first molding material 189, an upper semiconductor structure (second semiconductor structure; 102), and a second molding material 259. In an embodiment, the semiconductor package 100 may include a system in package (SiP).

A lower semiconductor structure (a first semiconductor structure; 101) includes a first substrate 110, first bridge dies 120, a first semiconductor stacking structure (a chiplet stacking structure; 130), and second semiconductor stacking structures (a high-bandwidth memory; 170).

The first substrate 110 has the first semiconductor stacking structure 130 and the second semiconductor stacking structures 170 disposed on the upper surface thereof. The first substrate 110 has external connection members 111, also described as external connection terminals, disposed on the lower surface thereof. The first substrate 110 is electrically connected to a second substrate 190 of the upper semiconductor structure 102 through the core balls 180.

The first substrate 110 includes a lower plate portion 110A and a sidewall portion 110B. The lower plate portion 110A may be described as a central portion or region, inner portion or region, or recessed portion, and the sidewall portion 110B may be described as an edge portion or region or outer portion or region surrounding the central portion or inner portion, or a protruding or raised portion. The sidewall portion 110B may include an inner sidewall, or four inner sidewalls including two first sidewalls facing each other and two second sidewalls facing each other and perpendicular to the two first sidewalls. The first substrate 110 includes a first cavity 110C defined by the lower plate 110A and the sidewall portion 110B. The lower plate portion 110A is defined as a substrate between a dotted line 110L and a dotted line 110R. The sidewall portion 110B is defined by a substrate outside the dotted line 110L and outside the dotted line 110R. Therefore, according to some embodiments, from a plan view, the sidewall portion 110B surrounds the lower plate portion 110A.

The lower plate portion 110A has the first semiconductor stacking structure 130 and the second semiconductor stacking structures 170 disposed on the upper surface thereof. Each stacking structure (e.g., either 130 or 170) includes a plurality of semiconductor dies vertically stacked on each other. The combination of the first semiconductor stacking structure 180 and the second semiconductor stacking structure 170 may be described as a first die group. The lower plate portion 110A has the external connection members 111 disposed on the lower surface thereof. The lower plate portion 110A includes the first bridge dies 120 in a first insulating layer 117. The lower plate portion 110A includes first wiring layer 112, first vias 113, second wiring layers 114, and the first insulating layer 117. The first wiring layer 112 is disposed between the first vias 113 and the external connection members 111. For example, each first via 113 may connect a corresponding external connection member 111 to a corresponding wiring portion of the first wiring layer 112. A wiring portion of the first wiring layer 112 may be, for example, a wiring line, or a connection pad. The first wiring layer 112 electrically connects the first vias 113 to the external connection members 111. The first vias 113 are disposed between the second wiring layer 114 and the first wiring layer 112. The first vias 113 electrically connect a corresponding wiring portion of the second wiring layer 114 to a corresponding wiring portion of the first wiring layer 112. The second wiring layer 114 is disposed between the connection members 131 and the first vias 113, and between the connection members 171 and the first via 113. The second wiring layer 114 electrically connects the connection members 131 to the first vias 113, and the connection members 171 to the first vias 113. In the lower plate portion 110A, the first insulating layer 117 surrounds and protects the first wiring layer 112, the first vias 113, the second wiring layer 114, and the first bridge dies 120. The first wiring layer 112, the first vias 113, and the second wiring layer 114 of the lower plate portion 110A are electrically connected to the connection members 131 with normal intervals P2 connected to the first semiconductor stacking structure 130, and to the connection members 171 with normal intervals P4 connected to the second semiconductor stacking structure 170.

In one embodiment, core balls 180 are disposed on the upper surface of the sidewall portion 110B (e.g., on the top-most surface of the outer portion). The sidewall portion 110B includes the first wiring layer 112 including a plurality of first wiring portions, the first vias 113, the second wiring layer 114 including a plurality of second wiring portions, the second vias 115, the third wiring layer 116 including a plurality of third wiring portions, and the first insulating layer 117. Each first wiring portion of the first wiring layer 112 is disposed between a corresponding first via 113 and a corresponding external connection member 111. The first wiring layer 112 electrically connects the first vias 113 to the external connection members 111. The first vias 113 are disposed between the second wiring layer 114 and the first wiring layer 112. The first vias 113 electrically connect the second wiring layer 114 to the first wiring layer 112. The second wiring layer 114 is disposed between the second vias 115 and the first vias 113. The second wiring layer 114 electrically connects the second vias 115 to the first vias 113. The second vias 115 are disposed between the third wiring layer 116 and the second wiring layer 114. The second vias 115 electrically connect the third wiring layer 116 to the second wiring layer 114. The third wiring layer 116 is disposed between the core balls 180 and the second vias 115. The third wiring layers 116 electrically connect the core balls 180 to the second vias 115. In the sidewall portion 110B, the first insulating layer 117 surrounds and protects the first wiring layer 112, the first vias 113, the second wiring layer 114, the second vias 115, and the third wiring layer 116.

In an embodiment, the first wiring layer 112, the first vias 113, the second wiring layer 114, the second vias 115, and the third wiring layer 116 may each include or be formed of at least one of copper, nickel, zinc, gold, silver, platinum, palladium, chromium, titanium, and an alloy thereof. In an embodiment, the first insulating layer 117 may include or be formed of FR-4. In an embodiment, the first insulating layer 117 may include or be formed of epoxy and glass fiber. In an embodiment, the first vias 113 and the second vias 115 may each include or have a conical shape with a diameter that narrows from the lower surface to the upper surface.

In an embodiment, the first vias 113 and the second vias 115 may each include or have a conical shape with a diameter that narrows from the upper surface to the lower surface. In an embodiment, the first vias 113 and the second vias 115 may each have a cylindrical shape with a constant diameter from the upper surface to the lower surface. In other embodiments, the first substrate 110 including fewer or more wiring layers and layers of vias is included within the scope of the present disclosure.

The first bridge dies 120 are disposed in the lower plate portion 110A of the first substrate 110. The first bridge dies 120 are formed on surfaces (e.g., bottom surfaces) of the first semiconductor stacking structure 130 and second semiconductor stacking structures 170 to connect internal circuits of the first semiconductor stacking structure 130 and second semiconductor stacking structures 170 to each other. The first bridge dies 120 each have side and lower (e.g., bottom) surfaces embedded in the first insulating layer 117 of the lower plate portion 110A, and have an upper (e.g., top) surface exposed from the first insulating layer 117 of the lower plate portion 110A. The first bridge dies 120 electrically connect the first semiconductor stacking structure 130 and the second semiconductor stacking structures 170. The first bridge die 120 includes a first connection line 121, a second connection line 122, and upper connection pads 123. A plurality of first connection lines 121 and second connection lines 122 may be included. In an embodiment, the first bridge die 120 may be a silicon bridge. Each first connection line 121 and second connection line 122 include a first end contacting an upper connection pad 123 connected to a respective connection member 131 and a second end contacting an upper connection pad 123 connected to a respective connection member 171. Each first connection line 121 electrically connects an upper connection pad 123 connected to a connection member 131 to an upper connection pad 123 connected to a connection member 171. Each second connection line 122 electrically connects an upper connection pad 123 connected to a different connection member 131 to an upper connection pad 123 connected to a different connection member 171. Each first connection line 121 and second connection line 122 quickly move data in the horizontal direction. The upper connection pads 123 of the first bridge die 120 are electrically connected to the connection members 131 with fine intervals P1 connected to the first semiconductor stacking structure 130, and to the connection members 171 with fine intervals P3 connected to the second semiconductor stacking structure 170.

In an embodiment, each first connection line 121, second connection line 122, and upper connection pad 123 may include or be formed of at least one of copper, nickel, zinc, gold, silver, platinum, palladium, chromium, titanium, and an alloy thereof.

According to the present disclosure, it is possible to electrically connect the I/O terminals with fine intervals of a high-bandwidth memory (HBM) and the I/O terminals with fine intervals of the chiplet stacking structure using the first bridge die 120. With this, high-performance HBMs and chiplet stacking structures may be applied to the semiconductor package 100.

The first semiconductor stacking structure (the chiplet stacking structure; 130) is disposed on and in (e.g., at least partially in) the first cavity 110C of the first substrate 110. The first semiconductor stacking structure 130 includes a first chiplet 140, a second chiplet 160 on the first chiplet 140, and an interconnect structure 150 between the first chiplet 140 and the second chiplet 160, a molding material 159, and connection members 131. A chiplet is a block manufactured by distinguishing the components of a high-performance processor according to their functions, and by selecting components to perform a particular function and placing them on an integrated circuit die. Chiplets that do not need to use the latest processes can be manufactured by applying inexpensive old processes, and chiplets that need to use the latest processes can be manufactured by applying the latest processes. As such, chiplets can be manufactured separately according to their functions, and the manufactured chiplets can be connected to manufacture a single high-performance processor. Each chiplet cannot operate as a unit chip, and a high-performance processor manufactured by connecting such chiplets can overcome the performance limitations of a conventional processor manufactured with a single chip.

The first chiplet 140 includes lower connection pads 141, through-substrate vias such as through silicon vias (TSVs) 142, upper connection pads 143, and a first chiplet base 144. In an embodiment, the first chiplet 140 may include circuitry for a central processing unit (CPU) or a graphic processing unit (GPU) and may function as a central processing unit (CPU) or a graphic processing unit (GPU), for example. The first chiplet 140 is electrically connected to the upper second chiplet 160 by the interconnect structure 150. The side surfaces of the first chiplet 140 are surrounded by molding material 159.

The lower connection pad 141 is disposed between the through silicon via 142 and the connection member 131. The lower connection pad 141 electrically connects the through silicon via 142 to the connection member 131.

The through silicon via 142 is disposed between the upper connection pad 143 and the lower connection pad 141. The through silicon via 142 electrically connects the upper connection pad 143 to the lower connection pad 141. The first end of the through silicon via 142 contacts the lower connection pad 141, and the second end of the through silicon via 142 contacts the upper connection pad 143. As such, the through silicon vias 142 are disposed in the first chiplet base 144 and connected to the second chiplet 160 through the first interconnect structure 150, thereby increasing the speed at which the first chiplet 140 and the second chiplet 160 can receive and respond to signals and power from each other.

The upper connection pad 143 is disposed between the through silicon via 142 and the lower bonding pad 151 of the interconnect structure 150. The upper connection pad 143 electrically connects the lower bonding pad 151 to the through silicon via 142.

The first chiplet base 144 includes the lower connection pads 141, the through silicon vias 142, and the upper connection pads 143 therein. The first chiplet base 144 may include or be formed of a silicon material. The first chiplet base 144 includes an active region therein. In an embodiment, the active region may include a logic circuit.

The lower connection pads 141, the through silicon vias 142, and the upper connection pads 143 are electrically connected to the first substrate 110 through the connection members 131 arranged with normal intervals P2. In an embodiment, the lower connection pads 141 and the upper connection pads 143 may each include or be formed of at least one of copper, aluminum, silver, tin, gold, nickel, lead, titanium, and an alloy thereof. In an embodiment, the through silicon via 142 may include or be formed of at least one of tungsten, aluminum, copper, and an alloy thereof.

The interconnect structure 150 is disposed between the first chiplet 140 and the second chiplet 160, and between the molding material 159 and the second chiplet 160. The interconnect structure 150 may include lower bonding pads 151, upper bonding pads 152, a lower silicon insulating layer 153, and an upper silicon insulating layer 154. The lower bonding pads 151 and upper bonding pads 152 may electrically connect the second chiplet 160 to the first chiplet 140. The lower silicon insulating layer 153 surrounds and insulates the side surfaces of the lower bonding pads 151, and the upper silicon insulating layer 154 surrounds and insulates the side surfaces of the upper bonding pads 152.

The first chiplet 140 and the second chiplet 160 may be bonded by hybrid bonding using the interconnect structure 150. Hybrid bonding is a method of bonding two devices by fusing the same materials of the two devices using the bonding properties of the same materials. Here, hybrid means the bonding of two different types, for example, a first type of metal-to-metal bonding and a second type of non-metal-to-non-metal bonding. According to hybrid bonding, I/O with a fine pitch may be formed.

The lower bonding pads 151 formed on the first chiplet 140 are directly bonded by metal-metal hybrid bonding with the upper bonding pads 152 formed under the second chiplet 160, and the lower silicon insulating layer 153 formed on the first chiplet 140 is directly bonded by non-metal-non-metal hybrid bonding with the upper silicon insulating layer 154 formed under the second chiplet 160. In an embodiment, the lower bonding pads 151 and the upper bonding pads 152 may include or be formed of copper. In another embodiment, the lower bonding pads 151 and the upper bonding pads 152 may be made of a metallic material capable of applying hybrid bonding. In an embodiment, the lower silicon insulating layer 153 and the upper silicon insulating layer 154 may include or be formed of silicon oxide or TEOS forming oxide. In an embodiment, the lower silicon insulating layer 153 and the upper silicon insulating layer 154 may include or be formed of SiO₂. In an embodiment, the lower silicon insulating layer 153 and the upper silicon insulating layer 154 may be silicon nitride, silicon oxynitride, or other suitable dielectric material. In an embodiment, the lower silicon insulating layer 153 and the upper silicon insulating layer 154 may include or be SiN or SiCN.

The second chiplet 160 is disposed on the first chiplet 140 and the molding material 159. The second chiplet 160 is electrically connected to the first chiplet 140 by the interconnect structure 150. In an embodiment, the second chiplet 160 may include static random access memory (SRAM). The second chiplet 160 includes an active region therein. In an embodiment, the active region may include a logic circuit. The side surfaces of the second chiplet 160 are surrounded by the first molding material 189. The footprint of the first chiplet 140 is included in the footprint of the second chiplet 160.

The molding material 159 surrounds the side surface of the first chiplet 140. The molding material 159 may have lower connection pads 141, conductive posts 145, and upper connection pads 143 disposed therein. By disposing the lower connection pads 141, the conductive posts 145, and the upper connection pads 143 inside the molding material 159, it is possible to increase the speed at which the second chiplet 160 and the second semiconductor stacking structure 170 can receive and respond to signals and power from each other through the first bridge die 120. The lower connection pads 141, the conductive posts 145, and the upper connection pads 143 are electrically connected to the first bridge die 120 through connection members 131 arranged with the fine intervals P1. In an embodiment, the molding material 159 may include epoxy molding compound (EMC).

The connection members 131 are disposed between the lower connection pads 141 and the upper connection pads 123 of the first bridge die 120, and between the lower connection pads 141 and the second wiring layer 114 of the lower plate portion 110A of the first substrate 110. The connection members 131 disposed between the lower connection pads 141 and the upper connection pads 123 of the first bridge die 120 are arranged with the fine intervals P1. The connection members 131 disposed between the lower connection pads 141 and the second wiring layers 114 of the lower plate portion 110A of the first substrate 110 are arranged with the normal intervals P2. As described herein, particularly when describing intervals within a particular chiplet or die, normal intervals are larger than fine intervals. The connection member 131 connects the lower connection pad 141 to the second wiring layer 114 of the lower plate portion 110A of the first substrate 110, and connects the lower connection pad 141 to the upper connection pad 123 of the first bridge die 120. In an embodiment, the connection members 131, also described as connection terminals, may include or be formed of micro bumps or solder balls. In an embodiment, the connection member 131 may include or be formed of at least one of tin, silver, lead, nickel, copper, or an alloy thereof.

Second semiconductor stacking structures 170 (e.g., high-bandwidth memory (HBM) chips) are disposed on and in the first cavity 110C of the first substrate 110. An HBM is a high-performance three-dimensional (3D) stacked dynamic random access memory RAM (DRAM). HBMs is manufactured by stacking memory dies and vertically performing hybrid bonding or using micro bumps to form a single memory stack. The HBM has multiple memory channels through a memory stack in which memory dies are stacked vertically, enabling both low latency and high bandwidth compared to conventional DRAM products, and reducing the total area occupied by individual DRAMs on the substrate. Therefore, it is advantageous for high-bandwidth compared to area, and has the advantage of reducing power consumption.

In some embodiments, the second semiconductor stacking structures 170 include a buffer die and a plurality of memory dies stacked on the buffer die. The second semiconductor stacking structures 170 include the connection members 171. The connection members 171 are disposed on the upper connection pads 123 of the first bridge die 120, and on the second wiring layers 114 of the lower plate portion 110A of the first substrate 110. The connection members 171 disposed on the upper connection pads 123 of the first bridge die 120 are arranged with the fine intervals P3. The connection members 171 disposed on the second wiring layers 114 of the lower plate portion 110A of the first substrate 110 are arranged with the normal intervals P4. The connection members 171 arranged with the fine intervals P3 electrically connect the second semiconductor stacking structure 170 to the first semiconductor stacking structure 130 through the first bridge die 120. The connection members 171 arranged with the normal intervals P4 electrically connects the second semiconductor stacking structure 170 to the lower plate portion 110A of the first substrate 110. In an embodiment, the connection members 171, also described as connection terminals, may include or be formed of micro bump or solder ball. In an embodiment, the connection members 171 may include or be formed of at least one of tin, silver, lead, nickel, copper, or an alloy thereof.

The core balls 180 are disposed between the sidewall portion 110B (e.g., edge portion, or outer portion) of the first substrate 110 and a sidewall portion 190B (e.g., edge portion, or outer portion) of the second substrate 190. The core balls 180 electrically connect the second substrate 190 to the first substrate 110. Therefore, according to the present disclosure, it is possible to simplify the manufacturing process and improve the yield by using pre-manufactured core balls 180 instead of metal posts.

The first molding material 189 is disposed between the first substrate 110 and the second substrate 190. The first molding material 189 molds the first semiconductor stacking structure 130, the second semiconductor stacking structures 170, and the core balls 180.

According to some embodiments, the upper semiconductor structure (the second semiconductor structure; 102) includes a second substrate 190, a second bridge die 210, a RFIC chip 220, a DDI chip 230, a sensor chip 240, and a PMIC chip 250.

The second substrate 190 is disposed on the first molding material 189. The second substrate 190 is electrically connected to the first substrate 110 through the core balls 180. The second substrate 190 has the RFIC chip 220, the DDI chip 230, the sensor chip 240, and the PMIC chip 250 disposed on the upper surface thereof. The chips formed on the second substrate 190 may be described as a second die group.

The second substrate 190 includes an upper plate portion 190A and the sidewall portion 110B (alternatively described as central and edge portions, or inner and outer portions). The second substrate 190 includes a second cavity 190C defined by the upper plate portion 190A and the sidewall portion 190B. The upper plate portion 190A is defined as a substrate between the dotted line 190L and the dotted line 190R. The sidewall portion 190B is defined as a substrate outside a dotted line 190L and outside a dotted line 190R. The sidewall portion 190B may include an inner sidewall, or four inner sidewalls including two first sidewalls facing each other and two second sidewalls facing each other and perpendicular to the two first sidewalls

The upper plate portion 190A has the RFIC chip 220, the DDI chip 230, the sensor chip 240, and the PMIC chip 250 disposed on the upper surface thereof. The upper plate portion 190A has the first molding material 189 disposed on the lower surface thereof. The upper plate portion 190A includes the second bridge die 210 in a second insulating layer 197. Though one bridge die 210 is shown, additional bridge dies may be included. The upper plate portion 190A includes fifth wiring layer 194, fourth vias 195, sixth wiring layer 196, and the second insulating layer 197.

The fifth wiring layer 194 is disposed under the fourth vias 195. The fifth wiring layer 194 is electrically connected to the fourth vias 195. The fourth vias 195 are disposed between the fifth wiring layer 194 and the sixth wiring layer 196. The fourth vias 195 electrically connect the sixth wiring layer 196 to the fifth wiring layer 194. The sixth wiring layer 196 is disposed between connection members 221, 231, 241, and 251 and the fourth vias 195. The sixth wiring layer 196 electrically connects the connection members 221, 231, 241, and 251 to the fourth vias 195. In the upper plate portion 190A, the second insulating layer 197 surrounds the fifth wiring layer 194, the fourth vias 195, the sixth wiring layer 196, and the second bridge dies 210. The fifth wiring layer 194, the fourth vias 195, and the sixth wiring layer 196 of the upper plate portion 190A are electrically connected to the connection members 231 at normal intervals P6 connected to the DDI chip 230, and to the connection members 241 at normal intervals P8 connected to the sensor chip 240.

The sidewall portion 190B has the RFIC chip 220 and the PMIC chip 250 disposed on the upper surface thereof. The sidewall portion 190B has the core balls 180 disposed on the lower surface thereof. The sidewall portion 110B includes fourth wiring layer 192, third vias 193, the fifth wiring layer 194, the fourth vias 195, the sixth wiring layer 196, and the second insulating layer 197. Wiring portions of the fourth wiring layer 192 are disposed between the core balls 180 and the third vias 193. These wiring portions of the fourth wiring layer 192 electrically connect the third vias 193 to the core balls 180. The third vias 193 are disposed between the fourth wiring layer 192 and the fifth wiring layer 194. The third vias 193 electrically connect wiring portions of the fifth wiring layer 194 to respective wiring portions of the fourth wiring layer 192. The fifth wiring layer 194 is disposed between the third vias 193 and the fourth vias 195. Wiring portions of the fifth wiring layer 194 electrically connect the fourth vias 195 to the third vias 193. The fourth vias 195 are disposed between the fifth wiring layer 194 and the sixth wiring layer 196. The fourth vias 195 electrically connects wiring portions of the sixth wiring layer 196 to respective wiring portions of the fifth wiring layer 194. The sixth wiring layer 196 is disposed between the connection members 221 and the fourth vias 195, and between the connection members 251 and the fourth vias 195. The sixth wiring layer 196 electrically connects the connection members 221 to the fourth vias 195, and the connection members 251 to the fourth vias 195. In the sidewall portion 190B, the second insulating layer 197 surrounds and protects the fourth wiring layer 192, the third vias 193, the fifth wiring layer 194, the fourth vias 195, and the sixth wiring layer 196.

In an embodiment, the fourth wiring layer 192, the third vias 193, the fifth wiring layer 194, the fourth vias 195, and the sixth wiring layer 196 may each include or be formed of at least one of copper, nickel, zinc, gold, silver, platinum, palladium, chromium, titanium, and an alloy thereof. In an embodiment, the second insulating layer 197 may include or be formed of FR-4. In an embodiment, the second insulating layer 197 may include or be formed of epoxy and glass fiber. In an embodiment, the third vias 193 and the fourth vias 195 may include or have a conical shape with a diameter that narrows from the lower surface to the upper surface. In an embodiment, the third vias 193 and the fourth vias 195 may include or have a conical shape with a diameter that narrows from the upper surface to the lower surface. In an embodiment, the third vias 193 and the fourth vias 195 may have a cylindrical shape with a constant diameter from the upper surface to the lower surface. In other embodiments, the second substrate 190 including fewer or more wiring layers and via layers is included within the scope of the present disclosure.

The second bridge die 210 is disposed on the upper plate portion 190A of the second substrate 190. The second bridge die 210 has side and lower surfaces embedded in the second insulating layer 197 of the upper plate portion 190A, and has an upper surface exposed from the second insulating layer 197 of the upper plate portion 190A. The second bridge die 210 electrically connects the DDI chip 230 and the sensor chip 240. The second bridge die 210 includes a third connection line 211 (e.g., a plurality of third connection lines), a fourth connection line 212 (e.g., a plurality of fourth connection lines), and upper connection pads 213. In an embodiment, the second bridge die 210 may include or be a silicon bridge. Each third connection line 211 includes a first end contacting the upper connection pad 213 connected to a connection member 231 and a second end contacting the upper connection pad 213 connected to a connection member 241. Each fourth connection line 212 includes a first end contacting the upper connection pad 213 connected to a connection member 231 and a second end contacting the upper connection pad 213 connected to a connection member 241. The third connection lines 211 and the fourth connection lines 212 each electrically connect a respective upper connection pad 213 connected to a respective connection member 231 and a respective upper connection pad 213 connected to a respective connection member 241. Each third connection line 211 and fourth connection line 212 quickly moves data in the horizontal direction. The upper connection pads 213 of the second bridge die 210 are electrically connected to the connection members 231 with fine intervals P5 connected to the DDI chip 230, and to the connection members 241 with fine intervals P7 connected to the sensor chip 240. In an embodiment, each third connection line 211, fourth connection line 212, and upper connection pad 213 may include or be formed of at least one of copper, nickel, zinc, gold, silver, platinum, palladium, chromium, titanium, and an alloy thereof.

According to the present disclosure, it is possible to electrically connect the I/O terminals with fine intervals of each of the RFIC chip 220, DDI chip 230, sensor chip 240, and PMIC chip 250 using the second bridge die 210. With this, the high-performance RFIC chip 220, DDI chip 230, sensor chip 240, and PMIC chip 250 may be applied to the semiconductor package 100.

The RFIC chip 220 is a chip that transmits, receives, and amplifies RF signals from an antenna. The RFIC chip 220 is disposed on the second substrate 190. The RFIC chip 220 is electrically connected to the sixth wiring layer 196 of the second substrate 190 through the connection members 221. The connection members 221 are surrounded by an insulating member 222.

The DDI chip 230 is a chip that drives pixels of a display. The DDI chip 230 is disposed on the second substrate 190 and the second bridge die 210. The DDI chip 230 is electrically connected to the sixth wiring layer 196 of the second substrate 190 through the connection members 231 arranged with the normal intervals P6. The DDI chip 230 is electrically connected to the second bridge die 210 through the connection members 231 arranged with a fine interval P5. The DDI chip 230 is electrically connected to the sensor chip 240 through the second bridge die 210. The connection members 231 are surrounded by an insulating member 232.

The sensor chip 240 is disposed on the second substrate 190 and the second bridge die 210. The sensor chip 240 is electrically connected to the sixth wiring layer 196 of the second substrate 190 through the connection members 241 arranged with the normal intervals P8. The sensor chip 240 is electrically connected to the second bridge die 210 through the connection members 241 arranged with the fine intervals P7. The sensor chip 240 is electrically connected to the DDI chip 230 through the second bridge die 210. The connection members 241 are surrounded by an insulating member 242.

The PMIC chip 250 is a chip that receives the main power and converts, rectifies, distributes, and controls the main power into a stable and efficient voltage or current required by electronic devices.

The PMIC chip 250 is disposed on the second substrate 190. The PMIC chip 250 is electrically connected to the sixth wiring layer 196 of the second substrate 190 through the connection members 251. The connection members 251 are surrounded by an insulating member 252.

In an embodiment, the connection members 221, 231, 241, and 151 may include or be micro bumps or solder balls. In an embodiment, the connection members 221, 231, 241, and 151 may include or be formed of at least one of tin, silver, lead, nickel, copper, or an alloy thereof. In an embodiment, the insulating members 222, 232, 242, and 252 may include or be underfill members.

The second molding material 259 is disposed on the second substrate 190. The second molding material 259 molds the RFIC chip 220, DDI chip 230, sensor chip 240, and PMIC chip 250. The upper surfaces of each of the RFIC chip 220, DDI chip 230, sensor chip 240, and PMIC chip 250 are exposed from the second molding material 259.

According to the present disclosure, it is possible to electrically connect the lower semiconductor structure 101 and the upper semiconductor structure 102 using the core balls 180, and dispose the first semiconductor stacking structure 130 and the second semiconductor stacking structures 170 in a cavity by forming a cavity in the first substrate 110 and the second substrate 190. With this, the thickness and area of the semiconductor package 100 may be reduced. The sum of a first depth H2 of the first cavity 110C of the first substrate 110, a height H3 of the core balls 180, and a second depth H4 of the second cavity 190C of the second substrate 190 is greater than a height H1 of the first semiconductor stacking structure 130 and a height H5 of the second semiconductor stacking structure 170. In this embodiment, the first semiconductor stacking structure 130 and second semiconductor stacking structure 170 each extends from the first cavity 110C upward to contact the first molding material 189, and a top-most surface of each stacking structure contacts the first molding material 189 in the second cavity 190C.

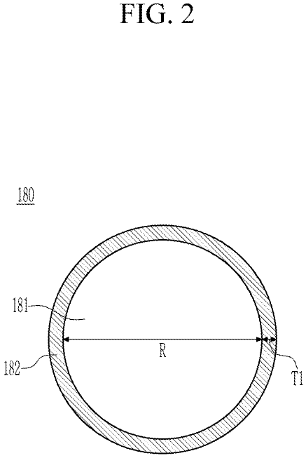

FIG. 2 is a cross-sectional view illustrating a core ball 180 according to an embodiment.

Referring to FIG. 2, the core ball 180 includes an inner core 181 and a first external conductive layer 182 covering the inner core 181. Additionally, although not shown, the core ball 180 may include at least one of a nickel layer and a copper layer between the inner core 181 and the first external conductive layer 182.

The inner core 181 serves as a support structure between the lower semiconductor structure 101 and the upper semiconductor structure 102. The inner core 181 relieves the stress applied to the core ball 180 from the lower semiconductor structure 101 and the upper semiconductor structure 102, allowing the core ball 180 to have a uniform height, thereby ensuring the interval between the lower semiconductor structure 101 and the upper semiconductor structure 102 is maintained constant.

In an embodiment, the inner core 181 may include or be formed of a plastic material, polymer material, or metal. In an embodiment, the plastic material may be a thermosetting resin, thermoplastic resin, or elastomer. In an embodiment, the thermosetting resin may include or be epoxy-based, melamine-formaldehyde-based, benzoguanamine-formaldehyde-based, divinylbenzene, divinyl ether, oligo or polydiacrylate, and alkylenebisacrylamide resin. In an embodiment, the thermoplastic resin may include or be polyvinyl chloride, polyethylene, polystyrene, nylon, or polyacetal resin. In an embodiment, the polymer material may include or be natural rubber or synthetic rubber. In an embodiment, the metal may include or be copper or a copper alloy. In an embodiment, the cross-sectional diameter or width (R) of the inner core 181 may be about 10 μm to about 300 μm.

The first external conductive layer 182 serves to transmit signals between the first substrate 110 and the second substrate 190. In an embodiment, the first external conductive layer 182 may be a SAC solder alloy including or formed of tin, silver, and copper. In an embodiment, the first external conductive layer 182 may include or be formed of at least one of gold, silver, nickel, zinc, tin, aluminum, chromium, antimony, and an alloy thereof. In an embodiment, a thickness T1 of the first external conductive layer 182 may be about 1 μm to about 5 μm. A thickness T1 of the first external conductive layer 182 may be about 1/10 to 1/100 of the diameter R of the inner core 181.

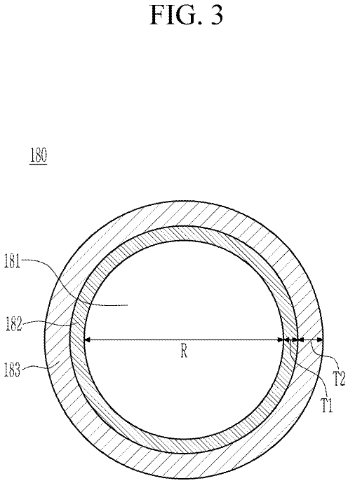

FIG. 3 is a cross-sectional view illustrating a core ball 180 according to another embodiment.

Referring to FIG. 3, the core ball 180 includes a second external conductive layer 183 covering the first external conductive layer 182. By adding a second external conductive layer 183 to the first external conductive layer 182 of the core ball 180, the speed at which signals and power are transmitted between the first substrate 110 and the second substrate 190 can be improved. In an embodiment, the second external conductive layer 183 may be a SAC solder alloy including or formed of tin, silver, and copper. In an embodiment, the second external conductive layer 183 may include or be formed of at least one of copper, gold, silver, nickel, zinc, tin, aluminum, chromium, antimony, and an alloy thereof. In an embodiment, the thickness T2 of the second external conductive layer 183 may be about 5 μm to about 50 μm. In this case, the combined thickness T1+T2 of the external conductive layers may be about ¼ to about 1/25 the diameter R of the inner core 181. In both FIG. 2 and FIG. 3, a core ball is shown to include an inner core, and an outer shell. Generally speaking, the core balls described herein have an inner core formed of a material that does not change shape when temperature rises to implement a reflow process, and an outer shell or covering that reflows when temperature rises to implement a reflow process and/or that can bond using thermal compression bonding. The material that forms the inner core, in some embodiments, is not electrically conductive. The material that forms the outer shell or covering is electrically conductive and is different from a material that forms the inner core.

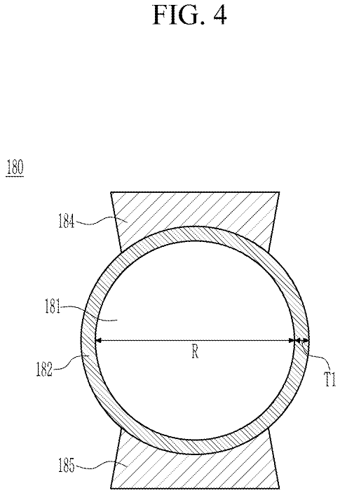

FIG. 4 is a cross-sectional view illustrating a core ball 180 according to another embodiment.

Referring to FIG. 4, the core ball 180 includes an upper conductive connection member 184 and a lower conductive connection member 185 connected to the first external conductive layer 182. The upper conductive connection member 184 and the lower conductive connection member 185 may each include a flat bonding surface. The flat bonding surfaces of the upper conductive connection member 184 and the lower conductive connection member 185 enable better bonding between the bonding surfaces when bonding the core ball 180 to other pads through a reflow process. The upper conductive connection member 184 and the lower conductive connection member 185 include side surfaces extend from the first external conductive layer 182 and that make an angle with the bonding surface of 90° or less. The side surfaces extending from the first external conductive layer 182 of the upper conductive connection member 184 and the lower conductive connection member 185, with a certain slope, are intended to maximize the area of the flat bonding surface of the upper conductive connection member 184 and the lower conductive connection member 185, which serves to ensure that reflow occurs in the flat bonding surface when the reflow process is performed.

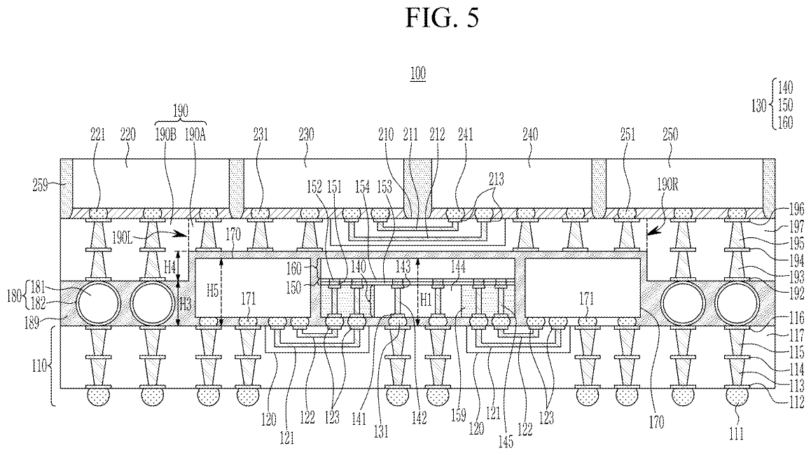

FIG. 5 is a cross-sectional view illustrating the semiconductor package 100 according to another embodiment.

Referring to FIG. 5, the first substrate 110 may not include a cavity. Depending on the device to which the semiconductor package 100 is applied, the first substrate 110 without a cavity may be used. The first semiconductor stacking structure 130, the high-bandwidth memories 170, and the core balls 180 are disposed on the upper surface of the first substrate 110. External connection members 111 are disposed on the lower surface of the first substrate 110. The first substrate 110 includes first bridge dies 120 in the first insulating layer 117.

The first substrate 110 includes the first wiring layer 112, the first vias 113, the second wiring layer 114, the second vias 115, the third wiring layer 116, and the first insulating layer 117. The first wiring layer 112 is disposed between the first vias 113 and the external connection members 111. The first wiring layer 112 electrically connects the first vias 113 to the external connection members 111. The first vias 113 are disposed between the second wiring layer 114 and the first wiring layer 112. The first vias 113 electrically connect the second wiring layer 114 to the first wiring layer 112. The second wiring layer 114 is disposed between the second via 115s and the first vias 113. The second wiring layer 114 electrically connects the second vias 115 to the first vias 113. The second vias 115 are disposed between the third wiring layer 116 and the second wiring layer 114. The second vias 115 electrically connects the third wiring layer 116 to the second wiring layer 114. The third wiring layer 116 is disposed between the core balls 180 and the second vias 115, between the connection members 131 and the second vias 115, and between the connection members 171 and the second vias 115. The third wiring layer 116 electrically connects the core balls 180 to the second vias 115, the connection members 131 to the second vias 115, and the connection members 171 to the second vias 115. The first insulating layer 117 surrounds the first wiring layer 112, the first vias 113, the second wiring layer 114, the second vias 115, the third wiring layer 116, and the first bridge dies 120.

The first wiring layer 112, the first vias 113, the second wiring layer 114, the second vias 115, and the third wiring layers 116 of the first substrate 110 are electrically connected to the connection members 131 with the normal intervals P2 connected to the first semiconductor stacking structure 130, and to the connection members 171 with the normal intervals P4 connected to the second semiconductor stacking structure 170.

According to the present disclosure, it is possible to electrically connect the lower semiconductor structure 101 and the upper semiconductor structure 102 using the core balls 180, and dispose the first semiconductor stacking structure 130 and the second semiconductor stacking structures 170 in the second cavity 190C by forming the second cavity 190C in the second substrate 190. With this, the thickness and area of the semiconductor package 100 may be reduced. The sum of the height H3 of the core balls 180 and the second depth H4 of the second cavity 190C of the second substrate 190 is greater than the height H1 of the first semiconductor stacking structure 130 and the height H5 of the second semiconductor stacking structure 170.

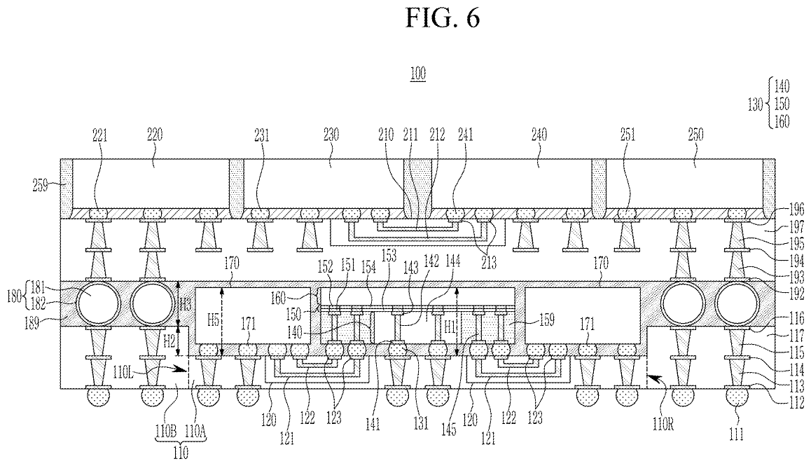

FIG. 6 is a cross-sectional view illustrating the semiconductor package 100 according to another embodiment.

Referring to FIG. 6, the second substrate 190 may not include a cavity. Depending on the device to which the semiconductor package 100 is applied, the second substrate 190 without a cavity may be used. The RFIC chip 220, the DDI chip 230, the sensor chip 240, and the PMIC chip 250 are disposed on the upper surface of the second substrate 190. Core balls 180 are disposed on the lower surface of the second substrate 190. The second substrate 190 includes the second bridge die 210 in the second insulating layer 197.

The second substrate 190 includes the fourth wiring layer 192, the third vias 193, the fifth wiring layer 194, the fourth vias 195, the sixth wiring layer 196, and the second insulating layer 197. The fourth wiring layer 192 is disposed between the core balls 180 and the third vias 193. The fourth wiring layer 192 electrically connects the third vias 193 to the core balls 180. The third vias 193 are disposed between the fourth wiring layer 192 and the fifth wiring layer 194. The third vias 193 electrically connect the fifth wiring layer 194 to the fourth wiring layer 192. The fifth wiring layer 194 is disposed between the third vias 193 and the fourth vias 195. The fifth wiring layer 194 electrically connects the fourth vias 195 to the third vias 193. The fourth vias 195 are disposed between the fifth wiring layer 194 and the sixth wiring layer 196. The fourth vias 195 electrically connect the sixth wiring layer 196 to the fifth wiring layer 194. The sixth wiring layer 196 is disposed between the connection members 221, 231, 241, and 251 and the fourth vias 195. The sixth wiring layer 196 electrically connects the connection members 221, 231, 241, and 251 to the fourth vias 195. The second insulating layer 197 surrounds the fourth wiring layer 192, the third vias 193, the fifth wiring layer 194, the fourth vias 195, the sixth wiring layer 196, and the second bridge die 210.

The fourth wiring layer 192, the third vias 193, the fifth wiring layer 194, the fourth vias 195, and the sixth wiring layer 196 of the second substrate 190 are connected to the connection members 221 with normal intervals connected to the RFIC chip 220, to the connection members 231 with the normal intervals P6 connected to the DDI chip 230, to the connection members 241 with the normal intervals P8 connected to the sensor chip 240, and to the connection members 231 with normal intervals connected to the PMIC chip 250.

According to the present disclosure, it is possible to electrically connect the lower semiconductor structure 101 and the upper semiconductor structure 102 using the core balls 180, and dispose the first semiconductor stacking structure 130 and the second semiconductor stacking structures 170 in the first cavity 110C by forming the first cavity 110C in the first substrate 110. With this, the thickness and area of the semiconductor package 100 may be reduced. The sum of the first depth H2 of the first cavity 110C of the first substrate 110 and the height H3 of the core balls 180 is greater than the height H1 of the first semiconductor stacking structure 130 and the height H5 of the semiconductor stacking structure 170.

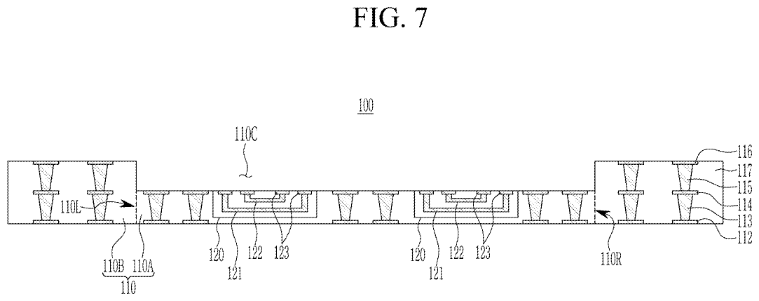

FIGS. 7 to 16 are cross-sectional views illustrating a method for manufacturing the semiconductor package 100 according to the embodiment of FIG. 1. The manufacturing method of FIGS. 7 to 16 may also be applied to the method for manufacturing the semiconductor package 100 of FIGS. 5 and 6, and may be applied to any of the example core balls described in FIGS. 2-4.

FIG. 7 is a cross-sectional view illustrating the step of providing the first substrate 110 on which the first cavity 110C is formed.

Referring to FIG. 7, the first substrate 110 on which the first cavity 110C is formed is provided. The first substrate 110 includes the first bridge dies 120 therein. In an embodiment, the first substrate 110 may include a printed circuit board (PCB). In an embodiment, the first substrate 110 may include an embedded trace substrate (ETS).

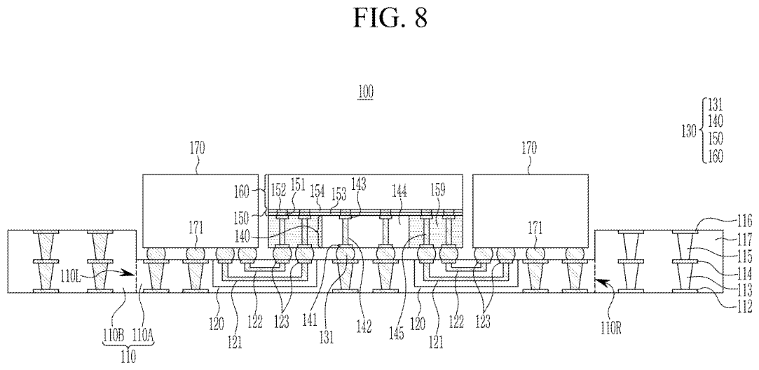

FIG. 8 is a cross-sectional view illustrating the step of mounting the first semiconductor stacking structure 130 and the second semiconductor stacking structures 170 on the first cavity 110C of the first substrate 110.

Referring to FIG. 8, the first semiconductor stacking structure 130 and the second semiconductor stacking structures 170 are mounted on the first cavity 110C of the first substrate 110 by flip chip bonding. The connecting members 131 arranged with normal intervals of the first semiconductor stacking structure 130 are bonded to the first substrate 110, and the connection members 131 arranged with fine intervals of the first semiconductor stacking structure 130 are bonded to the first bridge dies 120. The connecting members 171 arranged with normal intervals of the second semiconductor stacking structure 170 are bonded to the first substrate 110, and the connecting members 171 arranged with fine intervals of the second semiconductor stacking structure 170 are bonded to the first bridge die 120.

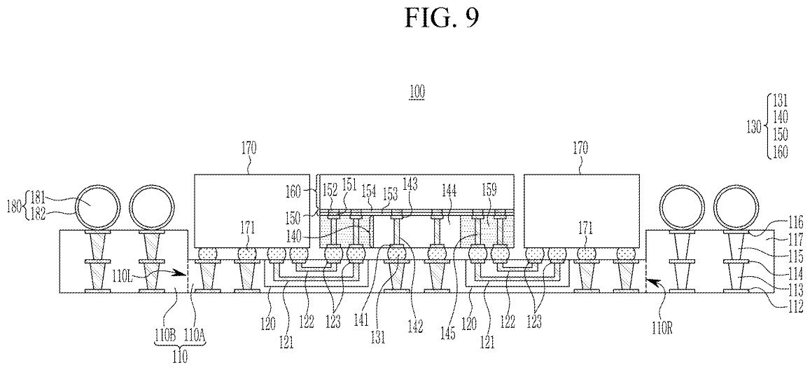

FIG. 9 is a cross-sectional view illustrating the step of bonding the core balls 180 on the sidewall portion 110B of the first substrate 110.

Referring to FIG. 9, the core balls 180 are bonded on the sidewall portion 110B (e.g., edge portion) of the first substrate 110 by performing a reflow process. As a result, though a precise spherical shape is shown for the core balls 180 in various figures, after the reflow process, a portion of the surface of the shell of the core balls that contacts wiring layer 116 may be flattened due to the reflow process. The flattening in some embodiments, may be minimized, by performing the reflow for a shorter period of time or at a lower temperature. Nonetheless, because the core balls 180 include inner core 181, which does not change shape during the reflow process, a height of the core balls 180 after reflow, and a distance between the first substrate 110 and second substrate 190 can be maintained at a predictable and uniform value.

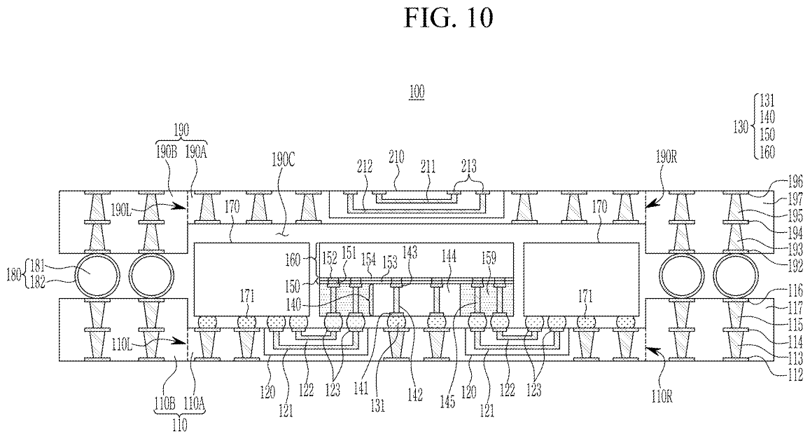

FIG. 10 is a cross-sectional view illustrating the step of bonding the second substrate 190 on which the second cavity 190C is formed on the core balls 180.

Referring to FIG. 10, the second substrate 190 on which the second cavity 190C is formed is bonded to the core balls 180. In one embodiment, a thermal compression (TC) process is performed to bond the first external conductive layer 182 of the core ball 180 and the fourth wiring layer 192 of the second substrate 190. As a result of the steps shown in FIGS. 9 and 10, a first portion (e.g. bottom portion) of each core ball 180 may be attached to a first conductive layer (e.g., wiring layer 116) of the substrate 110 of the lower semiconductor structure 101 by a first connection (e.g., a reflow connection), and a second portion (e.g., top portion) of each core ball 180 may be attached to a second conductive layer (e.g., wiring layer 192) of the substrate 190 of the second semiconductor structure 102 by a second connection different in structure from the first connection (e.g., a thermal compression connection).

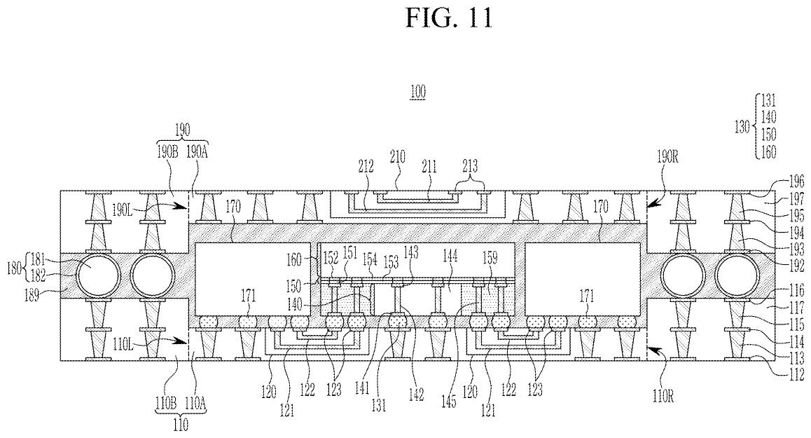

FIG. 11 is a cross-sectional view illustrating the steps of molding the first semiconductor stacking structure 130, the second semiconductor stacking structure 170, and the core balls 180 with the first molding material 189 between the first substrate 110 and the second substrate 190.

Referring to FIG. 11, between the first substrate 110 and the second substrate 190, the first semiconductor stacking structure 130, the second semiconductor stacking structures 170, and the core balls 180 are molded with the molding material 189. In an embodiment, the process of molding with the first molding material 189 may include a transfer molding process. In an embodiment, the first molding material 189 may be epoxy molding compound (EMC).

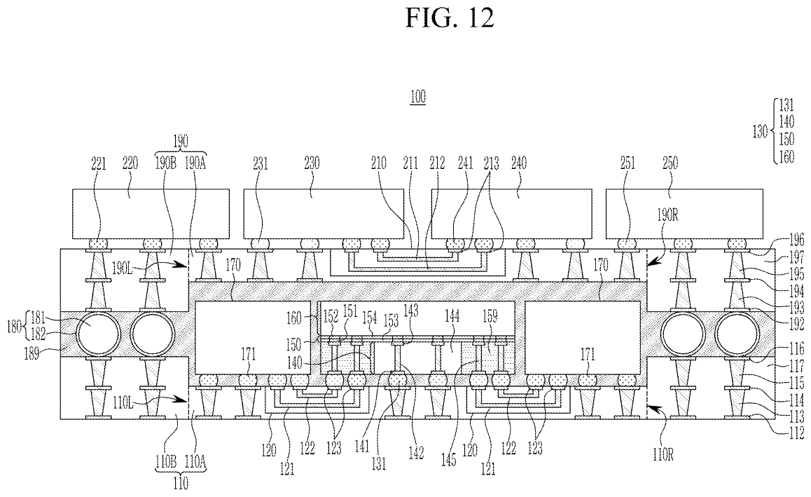

FIG. 12 is a cross-sectional view illustrating the steps of mounting the RFIC chip 220, the DDI chip 230, the sensor chip 240, and the PMIC chip 250 on the second substrate 190.

Referring to FIG. 12, the RFIC chip 220, the DDI chip 230, the sensor chip 240, and the PMIC chip 250 are mounted on the second substrate 190 by flip chip bonding. The RFIC chip 220, the DDI chip 230, the sensor chip 240, and the PMIC chip 250 are mounted on the second substrate 190 by performing a single reflow process. The connection members 221 arranged with normal intervals of the RFIC chip 220 are bonded to the second substrate 190. The connection members 231 arranged with normal intervals of the DDI chip 230 are bonded to the second substrate 190, and the connection members 231 arranged with fine intervals of the DDI chip 230 are bonded to the second bridge die 210. The connection members 241 arranged with normal intervals of the sensor chip 240 are bonded to the second substrate 190, and the connection members 241 arranged with fine intervals of the sensor chip 240 are bonded to the second bridge die 210. The connection members 251 arranged with normal intervals of the PMIC chip 250 are bonded to the second substrate 190.

Compared to the related art, which requires applying separate surface mount technology (SMT) to the upper and lower surfaces of the substrate, and may require flipping the device under manufacture multiple times during processing, according to the present disclosure, it is possible to reduce the time and cost required to perform the process by mounting the RFIC chip 220, the DDI chip 230, the sensor chip 240, and the PMIC chip 250 by performing a single reflow process only on the second substrate 190.

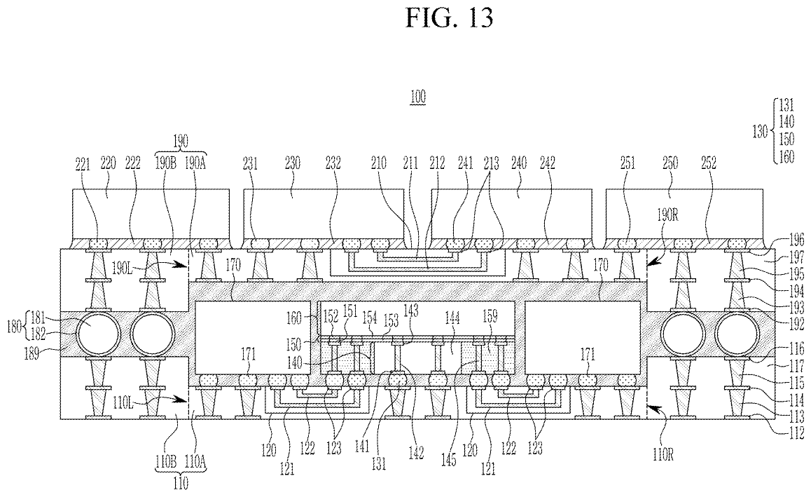

FIG. 13 is a cross-sectional view illustrating steps for underfilling the connection members 221 of the RFIC chip 220, the connection members 231 of the DDI chip 230, the connection members 241 of the sensor chip 240, and the connection members 251 of the PMIC chip 250.

Referring to FIG. 13, on the second substrate 190, a single underfill process is performed on the connection members 221 of the RFIC chip 220, the connection members 231 of the DDI chip 230, the connection members 241 of the sensor chip 240, and the connection members 251 of the PMIC chip 250. In an embodiment, the insulating member 222 surrounding the connection members 221 of the RFIC chip 220, the insulating member 232 surrounding the connection members 231 of the DDI chip 230, the insulating member 242 surrounding the connection members 241 of the sensor chip 240, and the insulating member 252 surrounding the connection members 251 of the PMIC chip 250 may include a non-conductive film (NCF) or molded under-fill (MUF).

Compared to the related art, which requires separate underfill processes for the connection components of each device mounted on the upper and lower surfaces of the substrate, according to the present disclosure, a single underfill process can be performed on the connection members 221 of the RFIC chip 220, the connection members 231 of the DDI chip 230, the connection members 241 of the sensor chip 240, and the connection members 251 of the PMIC chip 250 disposed on the second substrate 190, thereby reducing the time and cost required to perform the process.

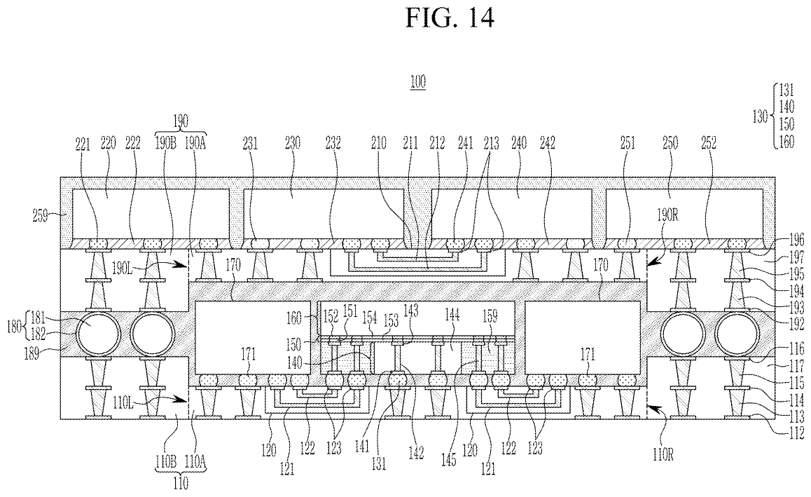

FIG. 14 is a cross-sectional view illustrating the step of molding the RFIC chip 220, the DDI chip 230, the sensor chip 240, and the PMIC chip 250 with the second molding material 259 on the second substrate 190.

Referring to FIG. 14, the RFIC chip 220, the DDI chip 230, the sensor chip 240, and the PMIC chip 250 are molded with the second molding material 259 on the second substrate 190. In an embodiment, the molding process with the second molding material 259 may include a compression molding or transfer molding process. In an embodiment, the second molding material 259 may be epoxy molding compound (EMC).

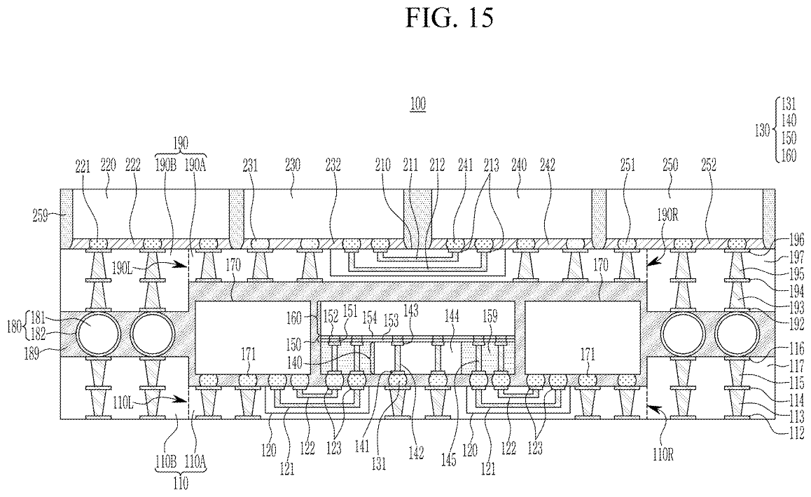

FIG. 15 is a cross-sectional view illustrating the step of planarizing the second molding material 259.

Referring to FIG. 15, chemical mechanical polishing (CMP) is performed to level the upper surface of the second molding material 259. The CMP process is applied to planarize the upper surface of the second molding material 259. After performing the CMP process, the upper surfaces of the RFIC chip 220, the DDI chip 230, the sensor chip 240, and the PMIC chip 250 are exposed.

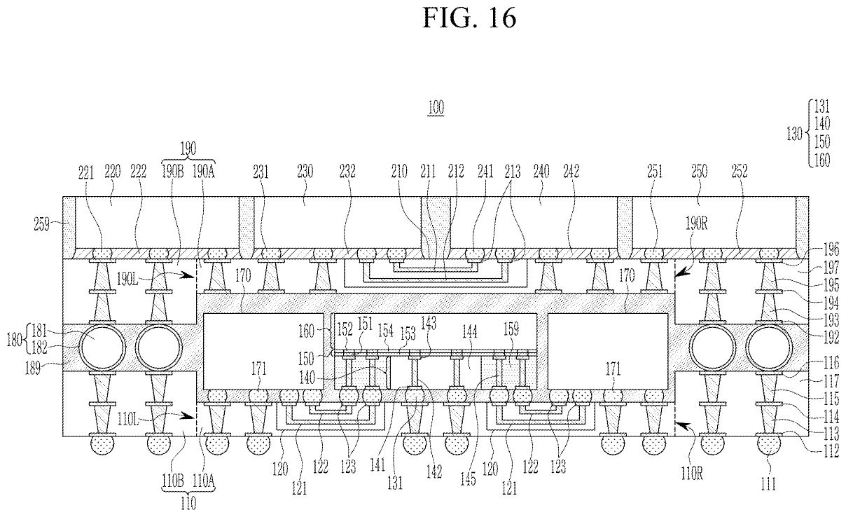

FIG. 16 is a cross-sectional view illustrating the step of forming the external connection members 111 on the lower surface of the first substrate 110.

Referring to FIG. 16, the external connection members 111 are formed on the lower surface of the first substrate 110. In an embodiment, the external connection members 111 may include or be formed of at least one of tin, silver, lead, nickel, copper, or an alloy thereof.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package, comprising:
a first semiconductor structure, including:
a first substrate; and
a semiconductor stacking structure including a plurality of semiconductor dies on the first substrate and including a top surface;
a second semiconductor structure on the first semiconductor structure, including:
a second substrate; and
a plurality of integrated circuit chips on the second substrate;
a plurality of core balls between the first substrate and the second substrate and electrically connecting the first semiconductor structure and the second semiconductor structure; and
a molding material covering the semiconductor stacking structure and the plurality of core balls between the first substrate and the second substrate.

2. The semiconductor package of claim 1, wherein:
each of the first substrate and the second substrate includes a printed circuit board (PCB).

3. The semiconductor package of claim 1, wherein:
the first substrate includes a first cavity,
the semiconductor stacking structure is disposed in the first cavity.

4. The semiconductor package of claim 3, wherein:
the plurality of integrated circuit chips include a radio frequency IC (RFIC) chip, a display driver IC (DDI) chip, a sensor chip, and a power management IC (PMIC) chip disposed on a first surface of the second substrate,
the second substrate includes a second cavity on a second surface opposite to the first surface, and
the second cavity covers the top surface of the semiconductor stacking structure.

5. The semiconductor package of claim 4, wherein:
the semiconductor stacking structure extends from the first cavity upward to contact the molding material, wherein the top surface of the semiconductor stacking structure contacts the molding material in the second cavity, and
the sum of a first depth of the first cavity, a height of the plurality of core balls, and a second depth of the second cavity is greater than the height of the semiconductor stacking structure.

6. The semiconductor package of claim 1, wherein:
the plurality of integrated circuit chips include a radio frequency IC (RFIC) chip, a display driver IC (DDI) chip, a sensor chip, and a power management IC (PMIC) chip disposed on a first surface of the second substrate, the second substrate includes a second cavity on a second surface opposite to the first surface,
the second cavity covers the upper surface of the semiconductor stacking structure.

7. The semiconductor package of claim 1, wherein:
each core ball of the plurality of core balls includes an inner core formed of a material that does not reflow during a reflow process, and a shell covering the inner core and formed of an electrically conductive material different from the material that forms the inner core.

8. The semiconductor package of claim 7, wherein:
a first portion of each core ball is attached to a first conductive layer of the first semiconductor structure by a reflow connection, and a second portion of each core ball is attached to a second conductive layer of the second semiconductor structure by a thermal compression connection.

9. The semiconductor package of claim 1, wherein the first semiconductor structure includes a first semiconductor stacking structure on the first substrate and that includes the plurality of semiconductor dies, and a plurality of second semiconductor stacking structures on the first substrate and disposed on at least on two opposite sides of the first semiconductor stacking structure, and further comprising:
a plurality of first bridge dies embedded in the first substrate,
wherein each of the plurality of first bridge dies electrically connects the first semiconductor stacking structure and a respective second semiconductor stacking structure of the plurality of second semiconductor stacking structures.

10. A semiconductor package, comprising:
a first semiconductor structure, including:
a first substrate;
a first semiconductor stacking structure on the first substrate; and
a plurality of second semiconductor stacking structures on the first substrate and disposed on at least on two opposite sides of the first semiconductor stacking structure;
a second semiconductor structure on the first semiconductor structure, including:
a second substrate; and
an RFIC chip, a DDI chip, a sensor chip, and a PMIC chip on the second substrate;
a plurality of core balls between the first substrate and the second substrate and electrically connecting the first semiconductor structure and the second semiconductor structure;
a first molding material covering the first semiconductor stacking structure, the plurality of second semiconductor stacking structures, and the plurality of core balls between the first substrate and the second substrate; and
a second molding material covering the RFIC chip, the DDI chip, the sensor chip, and the PMIC chip on the second substrate.

11. The semiconductor package of claim 10, wherein:
the first semiconductor structure further comprises a plurality of first bridge dies embedded in the first substrate,
each of the plurality of first bridge dies electrically connects the first semiconductor stacking structure and a respective second semiconductor stacking structure of the plurality of second semiconductor stacking structures.

12. The semiconductor package of claim 11, wherein:
the plurality of first bridge dies include silicon bridge dies.

13. The semiconductor package of claim 10, wherein:
the second semiconductor structure further comprises a second bridge die embedded in the second substrate, and
the second bridge die electrically connects the DDI chip and the sensor chip.

14. The semiconductor package of claim 10, wherein:
the first semiconductor stacking structure includes an application processor (AP).

15. The semiconductor package of claim 10, wherein:
the first semiconductor stacking structure includes a first chiplet and a second chiplet on the first chiplet.

16. The semiconductor package of claim 15, wherein:
the first chiplet includes a central processing unit (CPU) or a graphic processing unit (GPU).

17. The semiconductor package of claim 15, wherein:
the second chiplet includes a static random access memory (SRAM).

18. The semiconductor package of claim 10, wherein:
the plurality of second semiconductor stacking structures include a high bandwidth memory (HBM).

19. The semiconductor package of claim 10, wherein:
each core ball of the plurality of core balls includes an inner core formed of a material that does not reflow during a reflow process, and a shell covering the inner core and formed of an electrically conductive material different from the material that forms the inner core.

20. The semiconductor package of claim 19, wherein:
a first portion of each core ball is attached to a first conductive layer of the first substrate by a reflow connection, and a second portion of each core ball is attached to a second conductive layer of the second substrate by a thermal compression connection.
